(19) United States
(12) Patent Application Publication
(10) Pub. No.: US 2026/0219593 A1
(43) Pub. Date: Jul. 30, 2026

(54) LITHOGRAPHIC APPARATUS, INSPECTION SYSTEM, AND METHOD OF IMPLEMENTING PARALLEL SENSOR-HEADS WITH A COMMON RADIATION SOURCE

(71) Applicant: ASML Netherlands B.V., Veldhoven (NL)

(72) Inventors: Arjan Johannes Anton BEUKMAN, Son en Breugel (NL); Henricus Petrus Maria PELLEMANS, Veldhoven (NL)

(73) Assignee: ASML Netherlands B.V., Veldhoven (NL)

(21) Appl. No.: 19/152,840

(22) PCT Filed: Jan. 26, 2024
(86) PCT No.: PCT/EP2024/051937

§ 371 Date: Jul. 31, 2025

Related U.S. Application Data
(60) Provisional application No. 63/486,584, filed on Feb. 23, 2023.

(51) Int. Cl. G03F 9/00; G01B 11/27; G03F 7/00

(52) U.S. Cl. CPC G03F 9/7065; G01B 11/272; G03F 7/706849; G03F 7/706851; G03F 9/7003; G03F 9/7088

(57) ABSTRACT

A lithographic apparatus includes an illumination system, a projection system, and an inspection system. The inspection system includes a broadband radiation system, an optical system, wavelength separator system, and detector system. The broadband radiation system generates source radiation having a first set of narrowband wavelengths distributed within an operating bandwidth of the inspection system and a second set of narrowband wavelengths distributed within the operating bandwidth. A narrowband wavelength of the first set is proximal to a narrowband wavelength of the second set. The optical system directs first and second portions of the source radiation toward first and second targets to generate first and second scattered radiation. The wavelength separator system separates narrowband wavelengths of the first and second scattered radiation. The detector system receives the first and second scattered radiation to generate first and second measurement signals based on the first and second scattered radiation.

### CROSS-REFERENCE TO RELATED APPLICATION

This application claims priority of U.S. application 63/486,584 which was filed on 23 Feb. 2023 and which is incorporated herein in its entirety by reference.

### FIELD

The present disclosure relates to metrology apparatuses, for example, alignment sensors for measuring wafer alignment in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

A lithographic system can output only a finite number of fabricated devices in a given timeframe. Fabrication processes can include multiple complex, time-consuming steps to ensure sub-nanometer accuracy.

### SUMMARY

Accordingly, it is desirable to improve fabrication speed and throughput without sacrificing accurate lithographic pattern transfers. To increase throughput, inspection operations can be performed faster based on aspects described herein.

In some aspects, a lithographic apparatus can comprise an illumination system, a projection system, and an inspection system. The illumination system can illuminate a pattern of a patterning device. The projection system can project an image of the pattern onto a substrate to form a plurality of targets on the substrate. The inspection system can inspect the plurality of targets. The inspection system can comprise a broadband radiation system, an optical system, a wavelength separator system, and a detector system. The broadband radiation system can generate source radiation. The source radiation can have a first set of narrowband wavelengths distributed within an operating bandwidth of the inspection system. The source radiation can also have a second set of narrowband wavelengths distributed within the operating bandwidth. A narrowband wavelength of the first set can be proximal to a narrowband wavelength of the second set. The optical system can direct a first portion of the source radiation toward a first target of the plurality of targets to generate first scattered radiation. The optical system can also direct a second portion of the source radiation toward a second target of the plurality of targets to generate second scattered radiation. The wavelength separator system can separate narrowband wavelengths of the first and second scattered radiation. The detector system can receive the first and second scattered radiation. The detector system can also generate first and second measurement signals based on the first and second scattered radiation, respectively.

In some aspects, an inspection system can comprise a broadband radiation system, an optical system, a wavelength separator system, and a detector system. The broadband radiation system can generate source radiation. The source radiation can have a first set of narrowband wavelengths distributed within an operating bandwidth of the inspection system. The source radiation can also have a second set of narrowband wavelengths distributed within the operating bandwidth. A narrowband wavelength of the first set can be proximal to a narrowband wavelength of the second set. The optical system can direct a first portion of the source radiation toward a first target of a plurality of targets to generate first scattered radiation. The optical system can also direct a second portion of the source radiation toward a second target of the plurality of targets to generate second scattered radiation. The wavelength separator system can separate narrowband wavelengths of the first and second scattered radiation. The detector system can receive the first and second scattered radiation. The detector system can also generate first and second measurement signals based on the first and second scattered radiation, respectively.

In some aspects, a method can comprise one or more of the following operations. The method can comprise generating, using a broadband radiation system, source radiation. The source radiation can have a first set of narrowband wavelengths distributed within an operating bandwidth of an inspection system. The source radiation can also have a second set of narrowband wavelengths distributed within the operating bandwidth. A narrowband wavelength of the first set can be proximal to a narrowband wavelength of the second set. The method can further comprise directing a first portion of the source radiation toward a first target of a plurality of targets to generate first scattered radiation. The method can further comprise directing a second portion of the source radiation toward a second target of the plurality of targets to generate second scattered radiation. The method can further comprise separating, using a wavelength separator system, narrowband wavelengths of the first and second scattered radiation. The method can further comprise receiving the first scattered radiation at a detector system. The method can further comprise generating, using the detector system, a first measurement signal based on the first scattered radiation. The method can further comprise receiving the second scattered radiation at the detector system. The method can further comprise generating, using the detector system, a second measurement signal based on the second scattered radiation.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A, 4B, and 5 show inspection apparatuses, according to some aspects.

FIG. 6 shows a graph plot of wavelengths sourced from a broadband radiation system, according to some aspects.

FIG. 7 shows a flowchart of a method, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

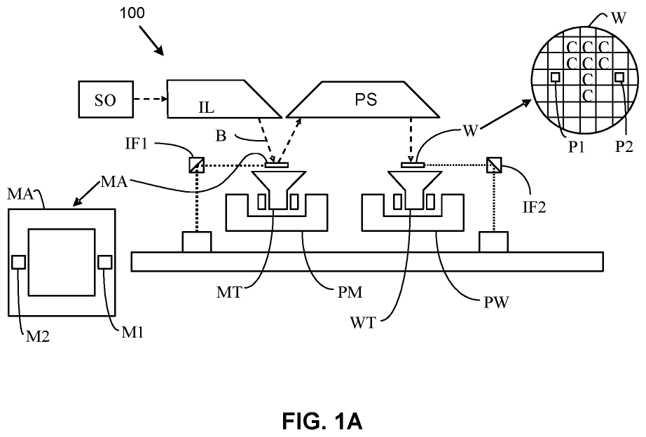

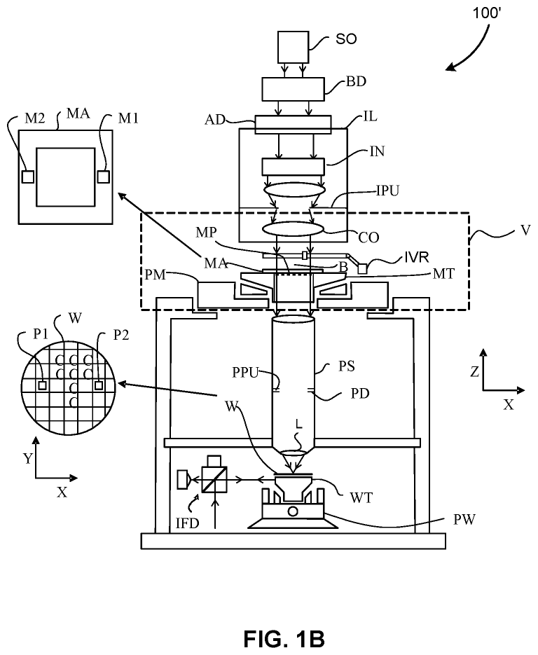

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

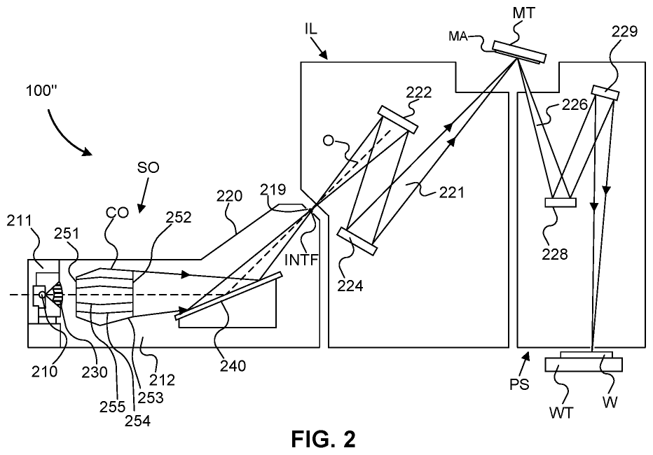

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

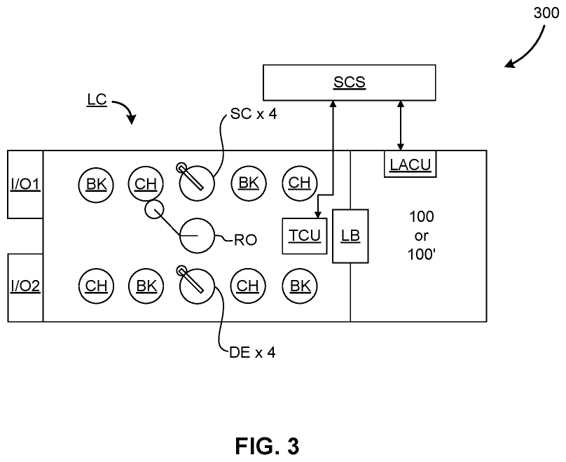

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

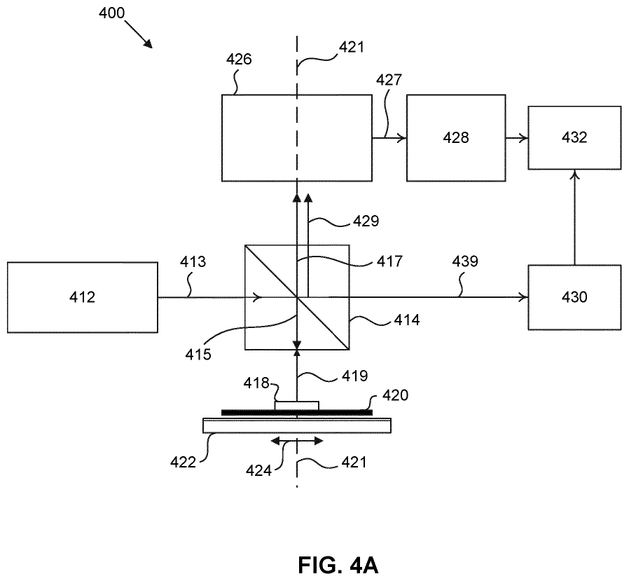

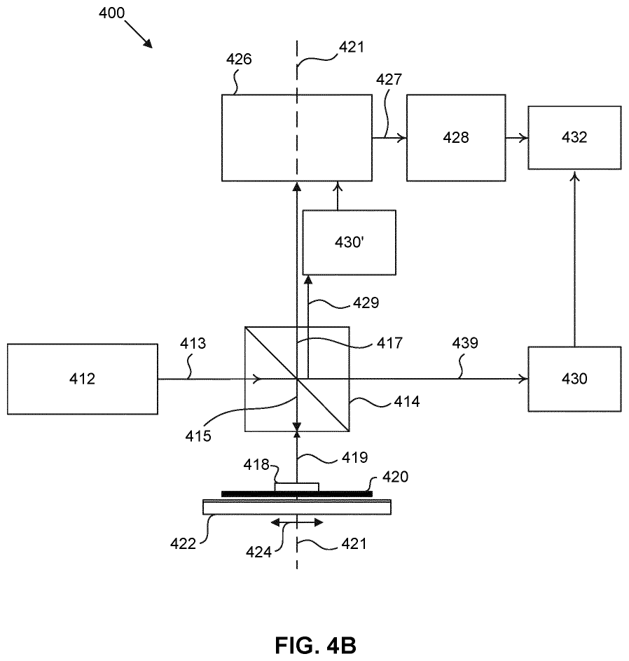

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders);
3. measuring position variations for various polarizations (position shift between polarizations); and
4. measuring intensity difference between opposite orders of a diffraction order pair (e.g., to characterize and correct for asymmetry).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some aspects, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Example Illumination Apparatus for Parallelized Sensors

In some aspects, the term “throughput” can be used to refer to a speed at which an amount of material or items pass through a system or process. For example, throughput can be used to characterize a rate of lithographic fabrication. As further examples, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each part of the process can involve tradeoffs that balance quality (e.g., sub-nanometer accuracy, high yield) and drawbacks (e.g., slower fabrication, cost). For example, to improve pattern-transfer accuracy, lithography can include inspection of printed marks on a substrate. Inspections performed by inspection apparatus 400 can ascertain a conformity or accuracy of a printed pattern on a substrate or align a substrate in order to properly receive a new pattern. However, the added time of the inspection operation can adversely impact throughput.

In some aspects, a wafer substrate can comprise tens, hundreds, thousands, or more inspection targets. A single inspection apparatus 400 can inspect multiple inspection targets serially (one at a time). The mark-to-mark movement of inspection apparatus 400 in between inspections can sometimes make up the majority of the time dedicated to metrology. That is, if mark-to-mark movement time could be reduced or eliminated, the result would be a significant enhancement of throughput. In some aspects, inspection solutions can be scaled (e.g., parallelizing multiple inspection apparatuses). However, scalability can be difficult to implement due to practical limitations. For example, scaling multiple iterations of inspection apparatus 400 would mean implementing multiples of illumination system 412. The power requirements alone can be prohibitive. On the other hand, powering multiple inspection apparatuses using a single illumination system can be prohibitive for other reasons (e.g., not enough power to go around). Without enough power/photons, inspection operations can lack the needed signal-to-noise ratio (SNR) for accurate measurements.

In some aspects, a broadband source (e.g., a white light source) can produce a powerful beam of radiation with photon wavelengths covering a broad spectrum. Inspection apparatus 400 may not need to use the entirety of the broad spectrum (e.g., can use select wavelengths). In this scenario, given wavelengths are used by inspection apparatus 400 while the excess photons in other wavelengths are thrown out. In other words, wasted photons are underutilized.

In some aspects, devices and functions described herein can be used for multiple sensor-head implementations using a shared radiation source.

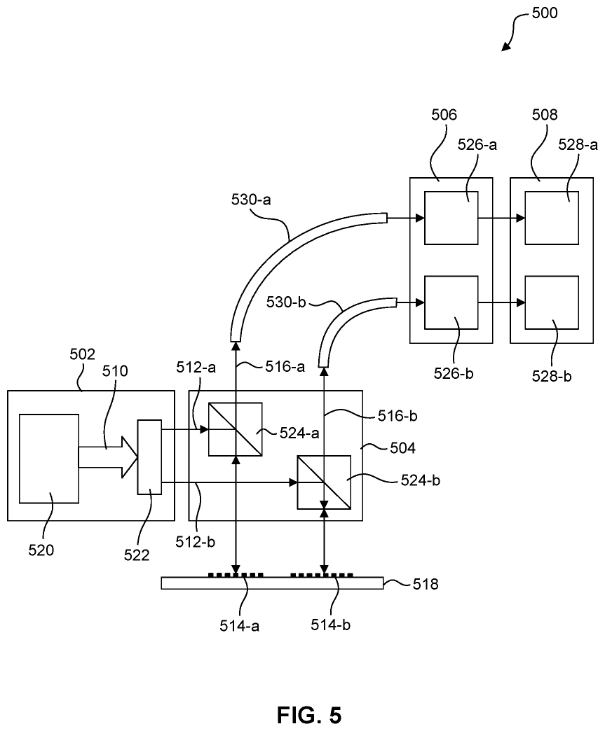

FIG. 5 shows an inspection system 500, according to some aspects. In some aspects, unless otherwise noted, the measurement operations described above in reference to inspection apparatus 400 (FIGS. 4A and 4B) can also be implemented with inspection system 500 (e.g., interferometry, signal processing, alignment position calculation, overlay calculation, or the like). One way in which FIG. 5 can differ from FIGS. 4A and 4B is the manner in which a single illumination source can be used to facilitate more than one sensor-head.

In some aspects, inspection system 500 can comprise a broadband radiation system 502, an optical system 504, a wavelength separator system 506, and a detector system 508. Broadband radiation system 502 can be configured to generate source radiation 510.

In some aspects, optical inspection of a target on a wafer can be performed using a plurality of colors (or wavelengths) of illumination. A given wavelength can provide information about the target that many not be readily apparent with another wavelength. Terms such as “multiple wavelengths,” “multiple photon frequencies,” “multiple parameter values,” or the like, can be used to refer to a set of discrete narrowbands within a broader range (a broadband). In a non-limiting example of a wavelength parameter, a first wavelength can be characterized as comprising a narrow band of wavelengths centered at a first central wavelength. A second wavelength can be similarly characterized as comprising a narrow band of wavelengths centered at a second central wavelength. A characterization of the first wavelength as being different from the second wavelength can be interpreted as the first central wavelength being different from the second central wavelength.

In some aspects, source radiation 510 can have a first set of narrowband wavelengths distributed within an operating bandwidth of inspection system 500 and a second set of narrowband wavelengths distributed within the operating bandwidth. As a non-limiting example, the operating bandwidth can be in the visible range (e.g., wavelengths approximately 400-700 nm), infrared (near and/or far), ultraviolet, extreme ultraviolet, or a combination thereof. In the visible range example, the first wavelength can be the color red while the second wavelength can be the color green. In another example, a narrowband wavelength of the first set can be proximal to a narrowband wavelength of the second set (e.g., both red wavelengths but offset by approximately 20 nm, 15 nm, 10 nm, 5 nm, or offset within a range such as 5 to 10 nm, 5 to 15 nm, 5 to 20 nm, 10 to 15 nm, 10 to 20 nm, or the like). The operating bandwidth of inspection system 500 can be, for example, approximately 2000 nm or less, 1600 nm or less, 1500 nm or less, 1200 nm or less, 1000 nm or less, 700 nm or less, 500 nm or less, 300 nm or less, or the like.

In some aspects, enumerative adjectives (e.g., “first,” “second,” “third,” or the like) can be used to distinguishing like elements without establishing an order, hierarchy, quantity, or permanent numeric assignment (unless otherwise noted). For example, the terms “first target” and “second target” can be used in a manner analogous to “i^{th} target” and “j^{th} target” so as to facilitate the distinguishing of two targets without specifying a particular order, hierarchy, quantity, or immutable numeric correspondence.

In some aspects, targets 514-a and 514-b can be alignment marks resulting from a pattern transfer onto substrate 518 via lithographic operations (e.g., as described in reference to FIGS. 1A, 1B, 2, and 3).

In some aspects, optical system 504 can be configured to direct a portion 512-a (e.g., first portion) of the source radiation toward target 514-a (e.g., first target) of a plurality of targets to generate scattered radiation 516-a (e.g., first scattered radiation) and to direct a portion 512-b (e.g., second portion) of source radiation 510 toward target 514-b (e.g., second target) of the plurality of targets to generate scattered radiation 516-b (e.g., second scattered radiation). It should be appreciated that the indices “a” and “b” can be generalized as an index “n” that can represent a quantity of two or more. The scalability illustrated in FIG. 5 is a non-limiting example where “n” represents a quantity of two (it is envisaged that the features in FIG. 5 can be scaled to quantities of three or more, five or more, ten or more, or the like).

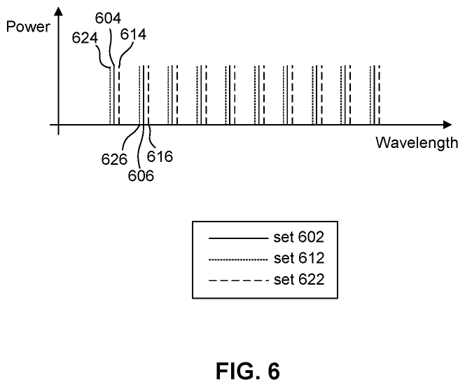

In some aspects, each of scattered radiation 516-a and 516-b can have multiple wavelengths. For example, scattered radiation 516-a can have the first set of narrowband wavelengths while scattered radiation 516-b can have the second set of narrowband wavelengths. In another example, scattered radiation 516-a can have one or more wavelengths from the first set of narrowband wavelengths and one or more wavelengths from the second set of narrowband wavelengths. Other combinations and/or permutations are envisaged. Wavelength distributions across multiple sensor-heads will be described in more detail further below (in reference to FIG. 6). The term “sensor-head” can be used herein to refer to the parts of inspection system 500 that are downstream of substrate 518 (e.g., the hardware responsible for collecting scattered radiation and/or detection).

In some aspects, wavelength separator system 506 can be configured to separate narrowband wavelengths of the first and second scattered radiation. Detector system 508 can be configured to receive the first and second scattered radiation. Detector system 508 can also be configured to generate measurement signals based on the scattered radiation 516-a and 516-b (e.g., generate first and second measurement signals). In the context of wavelength separation, different wavelengths are not limited to physical separation (e.g., spreading the light out into different colors). Wavelength ‘separation’ can refer to an implementation that allows an inspection technique to account for the use of two or more discrete wavelengths in a manner that yields additional or alternate measurement information when compared to an implementation that disregards the discretized wavelengths. Separation of wavelengths can be achieved by, for example, temporal separation (e.g., wavelength dependent delay), modulation of wavelengths via carrier signals, wavelength filters, or the like.

In some aspects, broadband radiation system 502 can comprise a broadband source (e.g., a white light laser for generating white light) and a filter system 522. Source radiation 510 can comprise coherent radiation, incoherent radiation, or a combination of both. Filter system 522 can comprise a multiplexer system (e.g., an apparatus that combines two or more narrowband wavelengths into single channels or beams). Filter system 522 can be configured to filter radiation such that portion 512-a of source radiation 510 has a first set of narrowband wavelengths and portion 512-b of source radiation 510 has a second set of narrowband wavelengths. The first and second sets of narrowband wavelengths can be the same or different.

In some aspects, optical system 504 can comprise optical structures 524-n (e.g., optical structures 524-a and 524-b; e.g., first and second optical structures). An optical structure can comprise, for example, a wedge, prism, reflector, beam splitter, refractive device, or the like). Optical structure 524-a can be configured to direct portion 512-a of source radiation 510 toward target 514-a. Optical structure 524-b can be configured to direct portion 512-b of source radiation 510 toward target 514-b. Via optical system 504, filter system 522 can be transmit the first set of narrowband wavelengths toward a first target and the second set of narrowband wavelengths toward a second target (and, by extension, an n^{th} set of narrowband wavelengths toward an n^{th} target).

In some aspects, wavelength separator system 506 can comprise a demultiplexer system that comprises wavelength separator devices 526-n (e.g., wavelength separator devices 526-a and 526-b; first and second wavelength separator devices). A wavelength separator device can comprise, for example, a dispersive device, dichroic mirror, refractive device, grating, filter (e.g., color filter), or the like.

In some aspects, detector system 508 can comprise detectors 528-n (e.g., detectors 528-a and 528-b; first and second detectors). In some aspects, a detector can comprise a single cell detector (e.g., single-pixel photodiode), two-dimensional detector array (e.g., multi-pixel camera), or the like. Each detector can generate a measurement signal that corresponds to the detected scattered radiation. The measurement signal can comprise data corresponding to the different narrowband wavelengths comprised in the detected scattered radiation. The measurement signal can be analyzed to infer information about a property of the target (e.g., alignment position, overlay error, or the like). Analysis of measurement radiation can be performed by a processor, computing device, or the like (e.g., processor 432 (FIG. 4)).

In some aspects, inspection system 500 can also comprise an optical fiber system comprising optical fibers 530-n (e.g., optical fibers 530-a and 530-b; first and second optical fibers). Optical fibers 530-n can allow footprint reduction for sensor-head components that are near the targets. In the specific, non-limiting example of FIG. 5, wavelength separator system 506 and/or detector system 508 can be implemented further away (e.g., remotely) while using optical fibers 530-n to guide the collected scattered radiation to the distant wavelength separator system 506 and/or detector system 508. Alternatively, or additionally, other optical hardware can be used to guide the scattered radiation (e.g., wedge, prism, reflector, beam splitter, refractive device, or the like).

FIG. 6 shows a graph plot 600 of sets of wavelengths that can be generated by a broadband radiation system, according to some aspects. In some aspects, features disclosed with respect to FIG. 6 can be implemented using the structures and functions described in reference to FIG. 5. When broadband source 520 is in the “on” state (e.g., producing radiation), all wavelengths within its operational spectrum can be generated at once. In other words, sets of narrowband wavelengths can be generated simultaneously by broadband radiation system 502.

In some aspects, the horizontal axis of graph plot 600 can represent a wavelength of radiation generated by a broadband radiation system (alternatively, a metric for photon frequency or energy can work just as well). The vertical axis of graph plot 600 can represent an intensity metric (e.g., energy, fluence, power, or the like). Sets of narrowband wavelengths 602, 612, and 622 (e.g., first, second, and third sets of narrowband wavelengths) are represented in graph plot 600, which can span an operating bandwidth of inspection system 500. Though three sets are shown, as few as two sets can also be implemented in sensor-head parallelization. And it is to be appreciated that additional sets can be implemented by using an appropriate wavelength offset to distinguish from the already existing sets.

In some aspects, using filter system 522, set of narrowband wavelengths 602 can be selected for portion 512-a of source radiation 510. Similarly, set of narrowband wavelengths 604 can be selected for portion 512-b of source radiation 510. Set of narrowband wavelengths 622 can be used for another parallel sensor-head.

In some aspects, set of narrowband wavelengths 602 can comprise narrowband wavelengths 604 and 606. Set of narrowband wavelengths 612 can comprise narrowband wavelengths 614 and 616. Set of narrowband wavelengths 622 can comprise narrowband wavelengths 624 and 626. As a non-limiting example, narrowband wavelength 604 can be in a range that can be considered ‘blue color’ (e.g., approximately 400 to 490 nm). For the purposes of this non-limiting example, let us assume narrowband wavelength 604 is approximately 440 nm.

In some aspects, broadband source 520 can have a limit to the amount of radiation power it can generate. When implementing, for example, two sensor-heads, it can be possible to operate the two sensor-heads at the same wavelengths (i.e., portions 512-a and 512-b of source radiation 510 can have the same wavelengths). While dividing photon count of the same wavelength in this manner can be acceptable if few sensor-heads are involved, dividing photon count too many times can result in slower measurement times (e.g., longer detector integration times can make up for the reduced photon count). This is counter to the goal of increasing throughput in lithographic fabrication. Therefore, since broadband source 520 can generate a full spectrum of photons within its operating bandwidth, and since a sensor-head uses a subset of that range (e.g., uses set of narrowband wavelengths 602), it is more efficient to put those would-be thrown out photons to use.

Referring back to the non-limiting example of narrowband wavelength 604 being approximately 440 nm, narrowband wavelength 614 can also be within the blue range (e.g., proximal to, but not equal to, narrowband wavelength 604 (440 nm)). As a non-limiting example, narrowband wavelength 614 can be 445 nm (e.g., offset by +5 nm). It is to be appreciated that, in a single sensor-head implementation, one set of narrowband wavelengths would be used while photons with wavelengths not in the set would be discarded. Now, in a multi sensor-head implementation, more of the spectrum can be used without waste. Wavelength offsets can have a magnitude of approximately 20 nm, 15 nm, 10 nm, 5 nm, or the like (or can be expressed as a range, for example, 5 to 10 nm, 5 to 15 nm, 5 to 20 nm, 10 to 15 nm, 10 to 20 nm, or the like).

In some aspects, the next group of wavelengths toward the right (e.g., narrowband wavelengths 606, 616, and 626) are envisaged to have a similar arrangement of wavelengths as previously described in reference to narrowband wavelengths 604, 614, and 624 (e.g., small offsets from one another). And while FIG. 6 explicitly illustrates three sets of narrowband wavelengths each having ten narrowband wavelengths, it is to be appreciated that fewer or more sets (and fewer or more narrowband wavelengths in each set) can be implemented depending on the needs of the inspection to be performed (e.g., alignment, overlay) as well as the number of sensor-heads to be implemented.

In this manner, in some aspects, multiple sensor-heads can be powered by a common broadband source 520 without compromising on photon count, as well as increasing measurement speeds. Measurement speed can be increased by avoiding a situation where a single sensor-head has to move long distances while going mark to mark. For example, after target 514-a is inspected using elements of inspection system 500 with index “a”, the inspection elements with index “b” can already be nearby, or at, target 514-b for immediate inspection, thereby reducing the amount of time inspection system 500 needs to move going from one mark to the next. One of the most time consuming steps in an inspection operation can be moving a sensor head from one mark to another.

In some aspects, other distributions of narrowband wavelengths across multiple sensor-heads are envisaged. For example, a portion of set of narrowband wavelengths 602 can be transmitted toward target 514-a while another portion set of narrowband wavelengths 602 can be transmitted toward target 514-b. With additional wavelengths remaining unused at this point, it is envisaged that the unused wavelengths can be used at additional sensor-heads. For example, at least a portion of set of narrowband wavelengths 612 (or 622) can be transmitted toward another target (e.g., a third target, fourth target, or more) to generate additional scattered radiation (e.g., third scattered radiation, fourth scattered radiation, or more). In which case, detector system 508 can receive the additional scattered radiation and generate an additional measurement signal (e.g., third measurement signal) based on the additional scattered radiation. The additional measurement signal can be analyzed to determine a property of the additional target (e.g., alignment position, overlay, or the like). In this manner, it is envisaged that multiple sensor-heads can be scaled up to cover tens or even hundreds of targets while using a common broadband source, thereby reducing costs by eliminating a need for additional radiation sources and increasing throughput by reducing the amount of mark-to-mark movement of inspection system 500.

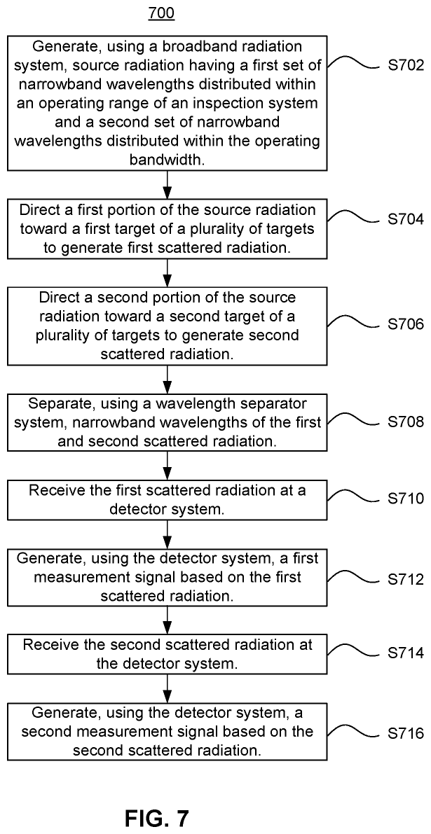

FIG. 7 shows a method 700, according to some aspects.

In some aspects, at step S702, source radiation 510 can be generated using broadband radiation system 502. Source radiation 510 can have a first set of narrowband wavelengths (e.g., set of narrowband wavelengths 602) distributed within an operating bandwidth of inspection system 500. Source radiation 510 can also have a second set of narrowband wavelengths (e.g., set of narrowband wavelengths 612) distributed within the operating bandwidth. A narrowband wavelength of the first set (e.g., narrowband wavelength 604) can be proximal to a narrowband wavelength of the second set (e.g., narrowband wavelength 614). The narrowband wavelengths of the second set, which traditionally would have been thrown out (had the broadband source been multiplied and scaled), is instead being used in a parallel sensor-head.

In some aspects, at step S704, a first portion (e.g., 512-a) of source radiation 510 can be directed toward a first target (e.g., 514-a) of a plurality of targets to generate first scattered radiation (e.g., 516-a).

In some aspects, at step S706, a second portion (e.g., 512-b) of source radiation 510 can be directed toward a second target (e.g., 514-b) of the plurality of targets to generate second scattered radiation (e.g., 516-b).

In some aspects, at step S708, narrowband wavelengths of the first and second scattered radiation can be separated using wavelength separator system 506.

In some aspects, at step S710, the first scattered radiation can be received at detector system 508.

In some aspects, at step S712, using detector system 508, a first measurement signal can be generated based on the first scattered radiation.

In some aspects, at step S714, the second scattered radiation can be received at detector system 508.

In some aspects, at step S716, using detector system 508, a second measurement signal can be generated based on the second scattered radiation.

The method steps of FIG. 7 can be performed in any conceivable order and it is not required that all steps be performed. Moreover, the method steps of FIG. 7 described above merely reflect an example of steps and are not limiting. That is, further method steps and functions are envisaged based aspects described in reference to FIGS. 1-6. The following is a non-exhaustive list of example steps that are envisaged based on descriptions of aspects disclosed herein. Further steps can comprise transmitting a portion of the first set of narrowband wavelengths toward the first target. Further steps can comprise transmitting another portion of the first set of narrowband wavelengths toward the second target. Further steps can comprise transmitting at least a portion of the second set of narrowband wavelengths toward a third target to generate third scattered radiation. Further steps can comprise receiving the third scattered radiation at detector system 508. Further steps can comprise generating, using detector system 508, a third measurement signal based on the third scattered radiation.

The embodiments may further be described using the following clauses:
1. A lithographic apparatus comprising:
   an illumination system configured to illuminate a pattern of a patterning device;
   a projection system configured to project an image of the pattern onto a substrate to form a plurality of targets on the substrate; and
   an inspection system configured to inspect the plurality of targets, the inspection system comprising:
      a broadband radiation system configured to generate source radiation having a first set of narrowband wavelengths distributed within an operating bandwidth of the inspection system and a second set of narrowband wavelengths distributed within the operating bandwidth, wherein a narrowband wavelength of the first set is proximal to a narrowband wavelength of the second set;
      an optical system configured to direct a first portion of the source radiation toward a first target of the plurality of targets to generate first scattered radiation and to direct a second portion of the source radiation toward a second target of the plurality of targets to generate second scattered radiation;
      a wavelength separator system configured to separate narrowband wavelengths of the first and second scattered radiation; and
      a detector system configured to receive the first and second scattered radiation and to generate first and second measurement signals based on the first and second scattered radiation, respectively.
2. The lithographic apparatus of clause 1, wherein the broadband radiation system comprises a filter system configured to transmit the first set of narrowband wavelengths toward the first target and the second set of narrowband wavelengths toward the second target.
3. The lithographic apparatus of clause 1, wherein:
   the plurality of targets comprises a third target configured to generate third scattered radiation; and
   the broadband radiation system comprises a filter system configured to:
      transmit a portion of the first set of narrowband wavelengths toward the first target,
      transmit another portion of the first set of narrowband wavelengths toward the second target, and
      transmit at least a portion of the second set of narrowband wavelengths toward the third target to generate the third scattered radiation; and
   the detector system is further configured to receive the third scattered radiation and to generate a third measurement signal based on the third scattered radiation.
4. The lithographic apparatus of clause 1, wherein the operating bandwidth is approximately 1600 nm or less.
5. The lithographic apparatus of clause 1, wherein the narrowband wavelength of the first set is offset from the narrowband wavelength of the second set by approximately 5 to 15 nm.
6. The lithographic apparatus of clause 1, wherein the wavelength separator comprises a demultiplexer system comprising a dispersive device, a grating, dichroic mirror, and/or a filter.
7. The lithographic apparatus of clause 1, wherein the inspection system further comprises an optical fiber system configured to direct the first and second scattered radiation toward the detector system.
8. The lithographic apparatus of clause 1, wherein the source radiation comprises coherent radiation.
9. The lithographic apparatus of clause 1, wherein the first and second set of narrowband wavelengths are generated simultaneously by the broadband radiation system.
10. An inspection system comprising:
   a broadband radiation system configured to generate source radiation having a first set of narrowband wavelengths distributed within an operating bandwidth of the inspection system and a second set of narrowband wavelengths distributed within the operating bandwidth, wherein a narrowband wavelength of the first set is proximal to a narrowband wavelength of the second set;
   an optical system configured to direct a first portion of the source radiation toward a first target of a plurality of targets to generate first scattered radiation and to direct a second portion of the source radiation toward a second target of the plurality of targets to generate second scattered radiation;
   a wavelength separator system configured to separate narrowband wavelengths of the first and second scattered radiation; and
   a detector system configured to receive the first and second scattered radiation and to generate first and second measurement signals based on the first and second scattered radiation, respectively.
11. The inspection system of clause 10, wherein the broadband radiation system comprises a filter system configured to transmit the first set of narrowband wavelengths toward the first target and the second set of narrowband wavelengths toward the second target.
12. The inspection system of clause 10, wherein:
   the plurality of targets comprises a third target configured to generate third scattered radiation; and
   the broadband radiation system comprises a filter system configured to:
      transmit a portion of the first set of narrowband wavelengths toward the first target,
      transmit another portion of the first set of narrowband wavelengths toward the second target, and
      transmit at least a portion of the second set of narrowband wavelengths toward the third target to generate the third scattered radiation; and
   the detector system is further configured to receive the third scattered radiation and to generate a third measurement signal based on the third scattered radiation.
13. The inspection system of clause 10, wherein the operating bandwidth is approximately 1600 nm or less.
14. The inspection system of clause 10, wherein the narrowband wavelength of the first set is offset from the narrowband wavelength of the second set by approximately 5 to 15 nm.
15. The inspection system of clause 10, wherein the wavelength separator comprises a demultiplexer system comprising a dispersive device, a grating, dichroic mirror, and/or a filter.
16. The inspection system of clause 10, wherein the inspection system further comprises an optical fiber system configured to direct the first and second scattered radiation toward the detector system.
17. The inspection system of clause 10, wherein the source radiation comprises coherent radiation.
18. The inspection system of clause 10, wherein the first and second set of narrowband wavelengths are generated simultaneously by the broadband radiation system.
19. A method of operating an inspection system, the method comprising:
   generating, using a broadband radiation system, source radiation having a first set of narrowband wavelengths distributed within an operating bandwidth of the inspection system and a second set of narrowband wavelengths distributed within the operating bandwidth, wherein a narrowband wavelength of the first set is proximal to a narrowband wavelength of the second set;
   directing a first portion of the source radiation toward a first target of a plurality of targets to generate first scattered radiation;
   directing a second portion of the source radiation toward a second target of the plurality of targets to generate second scattered radiation;
   separating, using a wavelength separator system, narrowband wavelengths of the first and second scattered radiation;
   receiving the first scattered radiation at a detector system;
   generating, using the detector system, a first measurement signal based on the first scattered radiation;
   receiving the second scattered radiation at the detector system; and
   generating, using the detector system, a second measurement signal based on the second scattered radiation.
20. The method of clause 19, further comprising:
   transmitting a portion of the first set of narrowband wavelengths toward the first target,
   transmitting another portion of the first set of narrowband wavelengths toward the second target, and
   transmitting at least a portion of the second set of narrowband wavelengths toward a third target to generate third scattered radiation;
   receiving the third scattered radiation at the detector system; and
   generating, using the detector system, a third measurement signal based on the third scattered radiation.

The terms “radiation,” “beam,” “light,” “illumination,” or the like can be used herein to refer to one or more types of electromagnetic radiation, for example, ultraviolet (UV) radiation (for example, having a wavelength, of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A lithographic apparatus comprising:
an illumination system configured to illuminate a pattern of a patterning device;
a projection system configured to project an image of the pattern onto a substrate to form a plurality of targets on the substrate; and
an inspection system configured to inspect the plurality of targets, the inspection system comprising:
a broadband radiation system configured to generate source radiation having a first set of narrowband wavelengths distributed within an operating bandwidth of the inspection system and a second set of narrowband wavelengths distributed within the operating bandwidth, wherein a narrowband wavelength of the first set is proximal to a narrowband wavelength of the second set;
an optical system configured to direct a first portion of the source radiation toward a first target of the plurality of targets to generate first scattered radiation and to direct a second portion of the source radiation toward a second target of the plurality of targets to generate second scattered radiation;
a wavelength separator system configured to separate narrowband wavelengths of the first and second scattered radiation; and
a detector system configured to receive the first and second scattered radiation and to generate first and second measurement signals based on the first and second scattered radiation, respectively.

2. The lithographic apparatus of claim 1, wherein the broadband radiation system comprises a filter system configured to transmit the first set of narrowband wavelengths toward the first target and the second set of narrowband wavelengths toward the second target.

3. The lithographic apparatus of claim 1, wherein:
the plurality of targets comprises a third target configured to generate third scattered radiation; and
the broadband radiation system comprises a filter system configured to:
transmit a portion of the first set of narrowband wavelengths toward the first target,
transmit another portion of the first set of narrowband wavelengths toward the second target, and
transmit at least a portion of the second set of narrowband wavelengths toward the third target to generate the third scattered radiation; and
the detector system is further configured to receive the third scattered radiation and to generate a third measurement signal based on the third scattered radiation.

4. The lithographic apparatus of claim 1, wherein the operating bandwidth is approximately 1600 nm or less.

5. The lithographic apparatus of claim 1, wherein the narrowband wavelength of the first set is offset from the narrowband wavelength of the second set by approximately 5 to 15 nm.

6. The lithographic apparatus of claim 1, wherein the wavelength separator comprises a demultiplexer system comprising a dispersive device, a grating, dichroic mirror, and/or a filter.

7. The lithographic apparatus of claim 1, wherein the inspection system further comprises an optical fiber system configured to direct the first and second scattered radiation toward the detector system.

8. The lithographic apparatus of claim 1, wherein the source radiation comprises coherent radiation.

9. The lithographic apparatus of claim 1, wherein the first and second set of narrowband wavelengths are generated simultaneously by the broadband radiation system.

10. An inspection system comprising:
a broadband radiation system configured to generate source radiation having a first set of narrowband wavelengths distributed within an operating bandwidth of the inspection system and a second set of narrowband wavelengths distributed within the operating bandwidth, wherein a narrowband wavelength of the first set is proximal to a narrowband wavelength of the second set;
an optical system configured to direct a first portion of the source radiation toward a first target of a plurality of targets to generate first scattered radiation and to direct a second portion of the source radiation toward a second target of the plurality of targets to generate second scattered radiation;
a wavelength separator system configured to separate narrowband wavelengths of the first and second scattered radiation; and
a detector system configured to receive the first and second scattered radiation and to generate first and second measurement signals based on the first and second scattered radiation, respectively.

11. The inspection system of claim 10, wherein the broadband radiation system comprises a filter system configured to transmit the first set of narrowband wavelengths toward the first target and the second set of narrowband wavelengths toward the second target.

12. The inspection system of claim 10, wherein:
the plurality of targets comprises a third target configured to generate third scattered radiation; and
the broadband radiation system comprises a filter system configured to:
transmit a portion of the first set of narrowband wavelengths toward the first target,
transmit another portion of the first set of narrowband wavelengths toward the second target, and
transmit at least a portion of the second set of narrowband wavelengths toward the third target to generate the third scattered radiation; and
the detector system is further configured to receive the third scattered radiation and to generate a third measurement signal based on the third scattered radiation.

13. The inspection system of claim 10, wherein the operating bandwidth is approximately 1600 nm or less.

14. The inspection system of claim 10, wherein the narrowband wavelength of the first set is offset from the narrowband wavelength of the second set by approximately 5 to 15 nm.

15. The inspection system of claim 10, wherein the wavelength separator comprises a demultiplexer system comprising a dispersive device, a grating, dichroic mirror, and/or a filter.
